(19) United States
(12) Patent Application Publication
(10) Pub. No.: US 2026/0293178 A1
(43) Pub. Date: Sep. 24, 2026

(54) SEMICONDUCTOR DEVICE, SEMICONDUCTOR MODULE, AND WIRELESS COMMUNICATION APPARATUS

(71) Applicant: SONY GROUP CORPORATION, Tokyo (JP)

(72) Inventors: Shin FUJII, Tokyo (JP); Kunihiko TASAI, Tokyo (JP)

(73) Assignee: SONY GROUP CORPORATION, Tokyo (JP)

(21) Appl. No.: 19/490,863

(22) PCT Filed: May 16, 2024
(86) PCT No.: PCT/JP2024/018104

§ 371 Date: Dec. 5, 2025

(30) Foreign Application Priority Data
Jul. 7, 2023 (JP) 2023-112091

(51) Int. Cl. H10D 30/47

(52) U.S. Cl. CPC H10D 30/471

(57) ABSTRACT

A semiconductor device according to one embodiment of the present disclosure includes: a substrate; a channel layer including a first nitride semiconductor provided on one surface of the substrate; a barrier layer including a second nitride semiconductor provided on a surface of the channel layer opposite to the substrate; a first semiconductor layer partially buried in the surface of the channel layer opposite to the substrate and being in contact with the barrier layer at at least a part of a side surface; and a second semiconductor layer provided on the first semiconductor layer and having a higher carrier concentration than the first semiconductor layer.

### TECHNICAL FIELD

The present disclosure relates to a semiconductor device, a semiconductor module, and a wireless communication apparatus.

### BACKGROUND ART

Patent Literature 1, for example, discloses a transistor having a multilayer structure in which a nitride-based channel layer and a barrier layer are formed in order on a substrate. The barrier layer is provided with a contact recessed portion in which a contact region of the channel layer is exposed. A contact layer is formed in the exposed contact region of the channel layer, and an ohmic contact is thereby formed on the contact layer.

### CITATION LIST

### Patent Literature

Patent Literature 1: Japanese Unexamined Patent Application Publication (Translation of PCT Application No.) 2007-538402

### SUMMARY OF THE INVENTION

Meanwhile, it is desired that a high electron mobility transistor (HEMT) widely used as a mobile phone terminal or a power amplifier for a base station be improved in output performance and efficiency.

It is therefore desirable to provide a semiconductor device, a semiconductor module, and a wireless communication apparatus with high output performance and high efficiency.

A semiconductor device according to one embodiment of the present disclosure includes: a substrate; a channel layer including a first nitride semiconductor provided on one surface of the substrate; a barrier layer including a second nitride semiconductor provided on a surface of the channel layer opposite to the substrate; a first semiconductor layer partially buried in the surface of the channel layer opposite to the substrate and being in contact with the barrier layer at at least a part of a side surface; and a second semiconductor layer provided on the first semiconductor layer and having a higher carrier concentration than the first semiconductor layer.

A semiconductor module according to one embodiment of the present disclosure includes the semiconductor device according to the embodiment of the present disclosure described above.

A wireless communication apparatus according to the present disclosure includes the semiconductor device according to the embodiment of the present disclosure described above.

The semiconductor device according to one embodiment of the present disclosure, the semiconductor module according to one embodiment, and the wireless communication apparatus according to one embodiment each have a multilayer structure in which the channel layer and the barrier layer are stacked in this order on a surface of the substrate. The multilayer structure includes the first semiconductor layer and the second semiconductor layer. The first semiconductor layer is partially buried in one surface of the channel layer opposite to the substrate, and is in contact with the barrier layer at at least a part of a side surface. The second semiconductor layer is provided on the first semiconductor layer and has a higher carrier concentration than the first semiconductor layer. This reduces contact resistance between the channel layer and an electrode formed on the second semiconductor layer.

### BRIEF DESCRIPTION OF THE DRAWINGS

FIG. 1 is a schematic cross-sectional diagram illustrating an exemplary configuration of a semiconductor device according to one embodiment of the present disclosure.

FIG. 2A is a schematic cross-sectional diagram illustrating an exemplary manufacturing method of the semiconductor device illustrated in FIG. 1.

FIG. 2B is a schematic cross-sectional diagram illustrating a step subsequent to FIG. 2A.

FIG. 2C is a schematic cross-sectional diagram illustrating a step subsequent to FIG. 2B.

FIG. 2D is a schematic cross-sectional diagram illustrating a step subsequent to FIG. 2C.

FIG. 2E is a schematic cross-sectional diagram illustrating a step subsequent to FIG. 2D.

FIG. 3 is a schematic cross-sectional diagram illustrating a configuration of a semiconductor device according to a comparative example.

FIG. 4 is a schematic cross-sectional diagram illustrating an exemplary configuration of a semiconductor device according to Modification Example 1 of the present disclosure.

FIG. 5 is a schematic cross-sectional diagram illustrating an exemplary configuration of a semiconductor device according to Modification Example 2 of the present disclosure.

FIG. 6 is a schematic cross-sectional diagram illustrating an exemplary configuration of a semiconductor device according to Modification Example 3 of the present disclosure.

FIG. 7 is a schematic cross-sectional diagram illustrating an exemplary configuration of a semiconductor device according to Modification Example 4 of the present disclosure.

FIG. 8 is a schematic cross-sectional diagram illustrating an exemplary configuration of a semiconductor device according to Modification Example 5 of the present disclosure.

FIG. 9 is a schematic cross-sectional diagram illustrating an exemplary configuration of a semiconductor device according to Modification Example 6 of the present disclosure.

FIG. 10 is a schematic cross-sectional diagram illustrating an exemplary configuration of a semiconductor device according to Modification Example 7 of the present disclosure.

FIG. 11 is a schematic cross-sectional diagram illustrating an exemplary configuration of a semiconductor device according to Modification Example 8 of the present disclosure.

FIG. 12 is a schematic cross-sectional diagram illustrating an exemplary configuration of a semiconductor device according to Modification Example 9 of the present disclosure.

FIG. 13 is a schematic perspective diagram illustrating a configuration of a semiconductor module.

FIG. 14 is a block diagram illustrating a configuration of a wireless communication apparatus.

### MODES FOR CARRYING OUT THE INVENTION

In the following, some embodiments of the present disclosure are described in detail with reference to the drawings. The following description is one specific example of the present disclosure, and the present disclosure is not limited to the embodiments described below. Further, the present disclosure is not limited to the embodiments described below in terms of arrangements, dimensions, dimension ratios, and the like of constituent elements illustrated in each of the drawings.

It is to be noted that the description is given in the following order.
1. Embodiment (An example of a semiconductor device including a contact layer that is partially buried in a channel layer and has a stacked structure in which a carrier concentration gradually increases from the channel layer)
   1-1. Configuration of Semiconductor Device
   1-2. Manufacturing Method of Semiconductor Device
   1-3. Workings and Effects
2. Modification Examples
   2-1. Modification Example 1 (Another example of the semiconductor device)
   2-2. Modification Example 2 (Another example of the semiconductor device)
   2-3. Modification Example 3 (Another example of the semiconductor device)
   2-4. Modification Example 4 (Another example of the semiconductor device)
   2-5. Modification Example 5 (Another example of the semiconductor device)
   2-6. Modification Example 6 (Another example of the semiconductor device)
   2-7. Modification Example 7 (Another example of the semiconductor device)
   2-8. Modification Example 8 (Another example of the semiconductor device)
   2-9. Modification Example 9 (Another example of the semiconductor device)
3. Application Examples
   3-1. Application Example to Semiconductor Module
   3-2. Application Example to Wireless Communication Apparatus

### 1. Embodiment

### 1-1. Configuration of Semiconductor Device

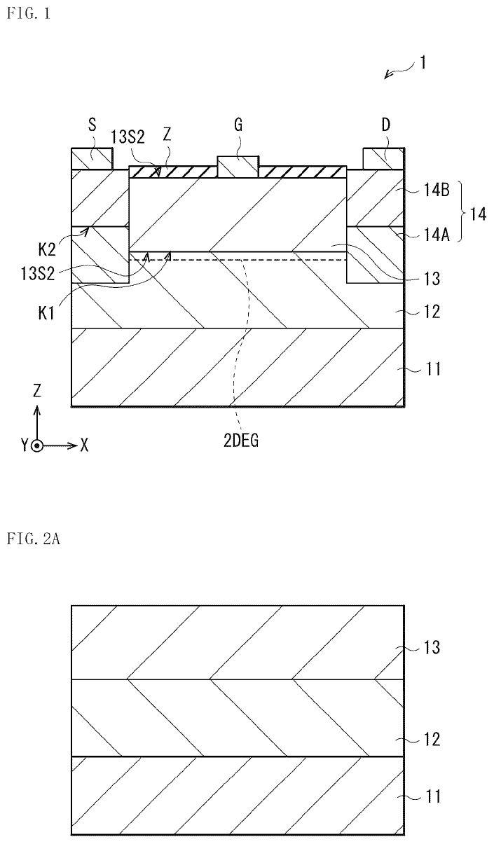

FIG. 1 schematically illustrates an exemplary cross-sectional configuration of a semiconductor device (semiconductor device 1) according to an embodiment of the present disclosure.

The semiconductor device 1 has a stacked structure in which a substrate 11, a channel layer 12, and a barrier layer 13 are stacked in order. The semiconductor device 1 further includes a contact layer 14 buried from a surface (surface 13S2) of the barrier layer 13 to the channel layer 12. The surface 13S2 is opposite to a surface (surface 13S1) of the barrier layer 13 opposed to the channel layer 12. The contact layer 14 includes a first contact layer 14A and a second contact layer 14B. The first contact layer 14A is partially buried in the channel layer 12 and is in contact with the barrier layer at a part of a side surface. The second contact layer 14B is provided on the first contact layer 14A and has a higher carrier concentration than the first contact layer 14A. The semiconductor device 1 further includes a gate electrode G, a source electrode S, a drain electrode D, and an insulating film Z. The semiconductor device 1 has, for example, a Schottky gate electrode structure. The gate electrode G and the insulating film Z are provided on the barrier layer 13, and the source electrode S and the drain electrode D are each provided on the contact layer 14.

The semiconductor device 1 according to the present embodiment is a high electron mobility transistor (HEMT) including a two-dimensional electron gas layer 2DEG as a channel. The two-dimensional electron gas layer 2DEG is generated owing to a difference between a magnitude of polarization of the channel layer 12 and a magnitude of polarization of the barrier layer 13. The two-dimensional electron gas layer 2DEG is generated in vicinity of an interface K1 of the channel layer 12 between the channel layer 12 and the barrier layer 13, for example.

The substrate 11 is a support of the semiconductor device 1. The substrate 11 is, for example, a Si (silicon) substrate. Used preferably as the Si substrate is, for example, a monocrystal Si (111) substrate having a (111) surface as a principal surface.

The channel layer 12 includes a nitride semiconductor having a bandgap smaller than a bandgap of the barrier layer 13. The channel layer 12 is configured to accumulate carriers at an interface close to the barrier layer 13, owing to the difference between the magnitude of polarization of the channel layer 12 and the magnitude of polarization of the barrier layer 13.

The channel layer 12 includes gallium nitride (GaN) epitaxially grown. The channel layer 12 may include undoped u-GaN to which no impurity is added. The channel layer 12 preferably has a thickness greater than or equal to 10 nm and less than or equal to 200 nm, for example. A total thickness of the channel layer 12 and a buffer layer described below is preferably greater than or equal to 1000 nm and less than or equal to 3000 nm, for example.

The barrier layer 13 includes a nitride semiconductor having a bandgap greater than the bandgap of the channel layer 12. The barrier layer 13 is configured to accumulate carriers in a region of the channel layer 12 near the barrier layer 13, owing to spontaneous polarization or piezoelectric polarization. Accordingly, the semiconductor device 1 is configured to form the two-dimensional electron gas layer 2DEG having high mobility and a high carrier concentration in the region in vicinity of the interface K1 of the channel layer 12 between the channel layer 12 and the barrier layer 13.

The barrier layer 13 includes Alₓ₂In_{y2}Ga_{(1-x2-y2)}N (0≤x2≤1, 0≤y2≤1) that is a nitride semiconductor epitaxially grown. For example, the barrier layer 13 may include undoped u-Alₓ₂In₍₁₋ₓ₂₎N to which no impurity is added. The barrier layer 13 includes AlInN epitaxially grown, for example. In this case, it is possible for the barrier layer 13 to have a small lattice mismatch with GaN, providing a superior mono-crystalline crystal.

The barrier layer 13 preferably has a thickness greater than or equal to 2.0 nm and less than or equal to 20 nm. In this case, it is possible for the barrier layer 13 to control a band profile of the semiconductor device 1 more appropriately. It is therefore possible to further increase the carrier density of the two-dimensional electron gas layer 2DEG generated in the channel layer 12.

The semiconductor device 1 may include another layer between the substrate 11 and the channel layer 12, and between the channel layer 12 and the barrier layer 13.

For example, a buffer layer may be provided between the substrate 11 and the channel layer 12. The buffer layer is configured to mitigate mismatch between a lattice constant of the substrate 11 and a lattice constant of the channel layer 12, for example. Accordingly, in a case where the buffer layer is provided, the substrate 11 may include a material having a lattice constant different from the lattice constant of the channel layer 12. The buffer layer includes, for example, GaN, AlGaN, or AlN.

A spacer layer including a nitride semiconductor having a bandgap greater than that of the channel layer 12 may be provided between the channel layer 12 and the barrier layer 13, for example. The spacer layer is configured to reduce alloy scattering between the channel layer 12 and the barrier layer 13, and suppress a decrease in carrier mobility of the two-dimensional electron gas layer 2DEG caused by the alloy scattering, for example. The spacer layer includes, for example, AlN, AlGaN, or AlInGaN.

The carrier density of the two-dimensional electron gas layer 2DEG is controllable based on a band profile of each layer from the barrier layer 13 to the channel layer 12, for example. One factor that determines the carrier density of the two-dimensional electron gas layer 2DEG is a height of a conduction band minimum of the barrier layer 13.

The polarization of each layer increases as each layer includes a Al composition at a higher rate, for example. Accordingly, a tilt of the conduction band minimum increases. Further, the height of the conduction minimum increases as the thickness of each layer increases. Accordingly, it is possible to increase the carrier density of the two-dimensional electron gas layer 2DEG by appropriately controlling the thickness and composition of each layer from the barrier layer 13 to the channel layer 12 and controlling the height of the conduction band minimum of the barrier layer 13.

The contact layer 14 constitutes a part of a current path between the source electrode S and the drain electrode D arranged with the gate electrode G interposed therebetween. As illustrated in FIG. 1, the contact layer 14 is provided below each of the source electrode S and the drain electrode D that are arranged with the gate electrode G interposed therebetween.

The contact layer 14 has a bottom surface located inside the channel layer 12, and an upper layer located above the surface 13S2 of the barrier layer 13. The contact layer 14 includes nitride gallium (GaN), and includes silicon (Si) as a dopant, for example.

The contact layer 14 has a multilayer structure in which the first contact layer 14A and the second contact layer 14B are stacked in this order from the channel layer 12. Here, the first contact layer 14A corresponds to one specific example of a “first semiconductor layer” according to an embodiment of the present disclosure. The second contact layer 14B corresponds to one specific example of a “second semiconductor layer” according to an embodiment of the present disclosure. The contact layer 14 is formed by metal organic chemical vapor deposition (MOCVD), molecular beam epitaxy (MBE), plasma enhanced CVD (PECVD), or sputtering.

The first contact layer 14A includes a nitride semiconductor having a carrier concentration lower than that of the second contact layer 14B. For example, the first contact layer 14A has a carrier concentration within a range greater than or equal to 10¹⁸ cm⁻³ and less than or equal to 10²¹ cm⁻³.

The second contact layer 14B includes a nitride semiconductor having a higher carrier concentration than that of the first contact layer 14A. For example, the second contact layer 14B has a carrier concentration within a range greater than 10¹⁸ cm⁻³ and less than or equal to 10²¹ cm⁻³.

The first contact layer 14A is partially buried in the channel layer 12, and is in contact with the barrier layer 13 at a side surface. The second contact layer 14B is stacked on the first contact layer 14A. In other words, an interface K2 between the first contact layer 14A and the second contact layer 14B is located above the channel layer 12. The first contact layer 14A preferably has a thickness greater than or equal to 3 nm and less than or equal to 200 nm to allow the part of the side surface to be in contact with the barrier layer 13, as described above. The first contact layer 14A has a thickness of 20 nm, for example. The second contact layer 14B preferably has a thickness that allows an upper surface of the second contact layer 14B to be formed above the surface 13S2 of the barrier layer 13. A total thickness of the first contact layer 14A and the second contact layer 14B is, for example, about 100 nm. The contact layer 14 preferably has a thickness greater than or equal to 10 nm and less than or equal to 100 nm, for example. For instance, the contact layer 14 has a thickness of 100 nm.

Each of the gate electrode G, the source electrode S, and the drain electrode D includes an electrically conductive material. The gate electrode G is disposed between the source electrode S and the drain electrode D. The gate electrode G is a Schottky gate in contact with the nitride semiconductor included in the barrier layer 13 without the insulating film Z, forming Schottky junction. For example, the gate electrode G may have a two-layer structure in which a nickel (Ni) layer and a gold (Au) layer are stacked in order on the barrier layer 13. The source electrode S and the drain electrode D may each have a structure in which a titanium (Ti) layer, an aluminum (Al) layer, a nickel (Ni) layer, and a gold (Au) layer are stacked in order on the contact layer 14.

The insulating film Z includes an insulating material. The insulating film Z is provided to cover a region of the surface 13S2 of the barrier layer 13 not covered with the gate electrode G. Examples of the constituent material of the insulating film Z include aluminum oxide (Al₂O₃), silicon dioxide (SiO₂), silicon nitride (Si₃N₄), or hafnium oxide (HfO₂). The insulating film Z may be a monolayer film including the constituent material described above, or a multilayer film including layers that includes the constituent materials described above.

### 1-2. Manufacturing Method of Semiconductor Device

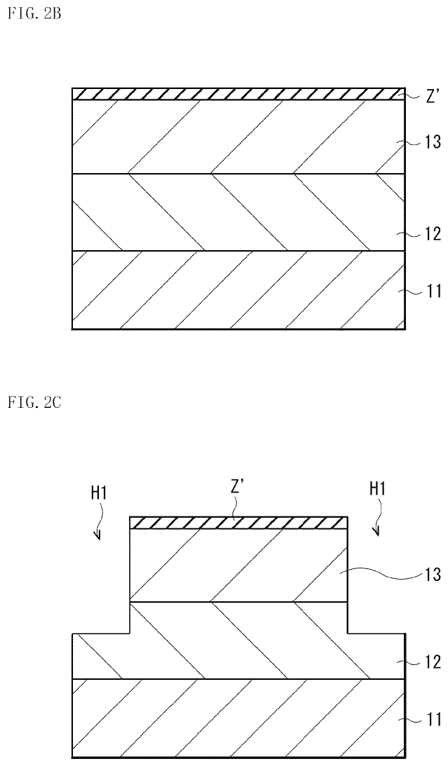

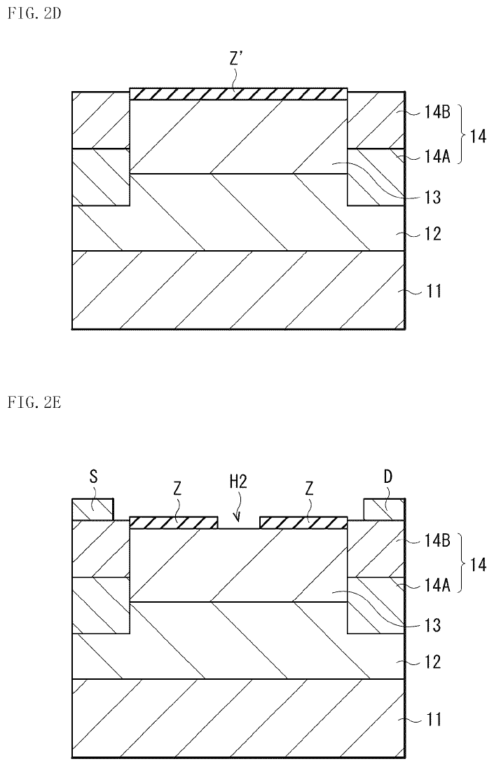

Next, an exemplary manufacturing method of the semiconductor device 1 according to the present embodiment is described with reference to FIGS. 2A to 2E. FIGS. 2A to 2E are schematic cross-sectional diagrams illustrating steps of the manufacturing method of the semiconductor device 1.

First, as illustrated in FIG. 2A, for example, the channel layer 12 and the barrier layer 13 are epitaxially grown on the substrate 11 in a sequential manner. It is to be noted that, in an example described below, a Si substrate is used as the substrate 11.

For example, the Si substrate having a (111) surface as a principal surface is set in a MOCVD apparatus, and is subjected to thermal cleaning at about 1000° C. for ten minutes. Further, in the case where the Si substrate is used, a buffer layer may be formed on the Si substrate. The buffer layer is formed by epitaxially growing GaN, AlGaN, or AlN to a thickness of 100 nm, to 2000 nm at about 900° C. to 1000° C., for example. Thereafter, the channel layer 12 is formed by epitaxially growing GaN to a thickness of 100 nm to 2000 nm at about 900° C. to 1100° C., for example. Next, the barrier layer 13 is formed on the channel layer 12 by epitaxially growing AlInN to a thickness of about 1 nm to 10 nm at 700° C. to 900° C., for example.

Next, as illustrated in FIG. 2B, SiN, SiO₂, Al₂O₃ or the like is deposited on the barrier layer 13 to form an insulating film Z′. Thereafter, as illustrated in FIG. 2C, parts of the insulating film Z′, the barrier layer 13, and the channel layer 12 are selectively removed in respective regions corresponding to the source electrode S and the drain electrode D, using a resist pattern having openings. That is, only regions of the barrier layer 13 and the insulating film Z′ in which the source electrode S and the drain electrode D are to be formed respectively are selectively removed to a depth reaching a middle of the channel layer 12. As a result, holes H1 are formed, and parts of the channel layer 12 are exposed.

Thereafter, as illustrated in FIG. 2D, a GaN layer having an n-type conductivity is grown by, for example, MOCVD or sputtering, and the first contact layer 14A and the second contact layer 14B are sequentially formed. At this time, Si is used as a dopant, and the dopant is so adjusted in concentration that the carrier concentration of the second contact layer 14B becomes higher than that of the first contact layer 14A. This achieves a device having low on-resistance (Ron).

Next, the insulating film Z′ on the barrier layer 13 is removed, following which a Ti layer, an Al layer, a Ni layer, and an Au layer are sequentially stacked on a contact layer 14 in a selective manner in the respective regions corresponding to the source electrode S and the drain electrode D, using a resist pattern having openings. Thereafter, the resist pattern is removed. Next, the insulating film Z is formed, and the insulating film Z is selectively removed in the respective regions corresponding to the source electrode S, the drain electrode D, and the gate electrode G, using a resist pattern having openings. That is, as illustrated in FIG. 2E, parts of the insulating film Z that are formed on the source electrode S and the drain electrode D and a part of the insulating film Z in which the gate electrode G is to be formed are selectively removed. Thereafter, the resist pattern is removed, following which a Ni layer and an Au layer are sequentially stacked on the exposed barrier layer 13 in a selective manner in the region corresponding to the gate electrode G, using a resist pattern having openings to form the gate electrode G. Thereafter, the resist pattern is removed.

The semiconductor device 1 according to the present embodiment illustrated in FIG. 1 is formed through the steps described above.

### 1-3. Workings and Effects

Recently, research and development of a HEMT including a nitride semiconductor have become active. The nitride semiconductor has a greater bandgap than Si, GaAs, or the like, and has particular hexagonal polarization. The HEMT including the nitride semiconductor is thus expected to be a low-resistance, high-voltage, and high-speed transistor.

Specifically, the HEMT is expected to be applied to a power device, a radio-frequency (RF) device, or the like. For example, a HEMT including an AlGaN barrier layer has been put to practical use in base stations for satellite communication or wireless communication. A HEMT including an AlInN barrier layer has a two-dimensional electron gas concentration higher than that of the HEMT including the AlGaN barrier layer, and is thus expected to have further higher output performance.

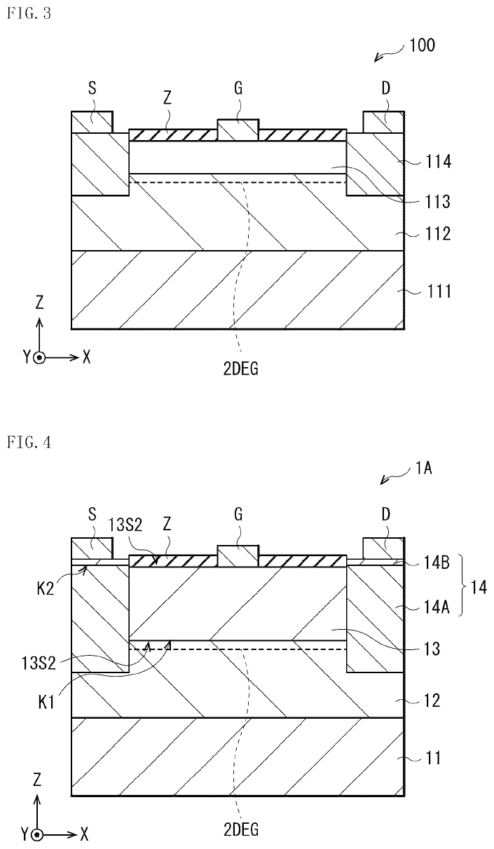

Meanwhile, a HEMT including a nitride semiconductor increases in contact resistance (Rc) between an ohmic electrode and a barrier layer in a case where the ohmic electrode is formed directly on the barrier layer. One means to address the problem involves, as illustrated in FIG. 3, forming a semiconductor layer (contact layer 114) including Si or the like as a dopant immediately below the source electrode S and the drain electrode D, which are ohmic electrodes, in the semiconductor device 100 in which the substrate 111, the channel layer 112, and the barrier layer 113 are stacked.

This method is expected to reduce the Rc as a doping concentration of the contact layer 114 is increased. However, the doping concentration has an upper limit, and a reduction in Rc greater than a certain level is thus not expected.

In contrast, in the multilayer structure according to the present embodiment in which the channel layer 2 and the barrier layer 13 are stacked in this order on the substrate 11, the contact layer 14 is formed that has the bottom surface located within the channel layer 12 and the upper surface located above the surface 13S2 of the barrier layer 13. The contact layer 14 has a multilayer structure in which the first contact layer 14A and the second contact layer 14B having a higher carrier concentration than the first contact layer 14A are formed in this order from the channel layer 12. The first contact layer 14A is buried in the channel layer 12, and is in contact with the barrier layer 13 at a part of a side surface. This reduces contact resistance of the channel layer 12 and the contact layer 14 (specifically, the first contact layer 14A) and contact resistance of the ohmic electrodes (specifically, the source electrode S and the drain electrode D) provided on the contact layer 14 and the contact layer 14 (specifically, the second contact layer 15B).

According to the semiconductor device 1 of the present embodiment described above, it is possible to achieve higher output performance and higher efficiency than a HEMT including a general nitride semiconductor.

Next, a description is given of Modification Examples 1 to 9, practical examples, and application examples of the present disclosure. It is to be noted that constituent elements corresponding to those of the semiconductor device according to the above-described embodiment are denoted with the same reference numerals to omit description thereof.

### 2. Modification Examples

### 2-1. Modification Example 1

FIG. 4 schematically illustrates an exemplary cross-sectional configuration of a semiconductor device (semiconductor device 1A) according to Modification Example 1 of the present disclosure.

In the example described in the foregoing embodiment, the interface K2 between the first contact layer 14A and the second contact layer 14B is formed above the channel layer 12. In the semiconductor device 1A according to the present modification example, however, the interface K2 between the first contact layer 14A and the second contact layer 14B is formed above the surface 13S2 of the barrier layer 13.

Also in this configuration, similar effects as those in the above-described embodiment are obtainable.

### 2-2. Modification Example 2

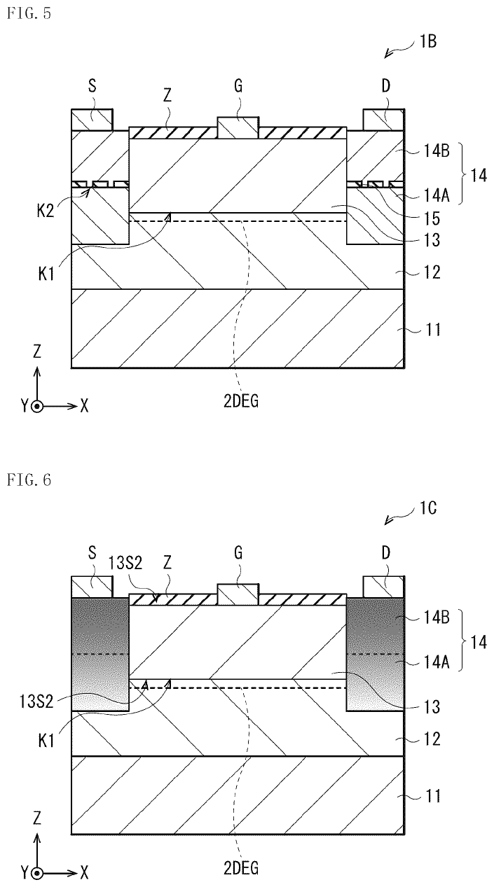

FIG. 5 schematically illustrates an exemplary cross-sectional configuration of a semiconductor device (semiconductor device 1B) according to Modification Example 2 of the present disclosure.

In the example described in the foregoing embodiment, the second contact layer 14B is stacked directly on the first contact layer 14A. In the semiconductor device 1B according to the present modification example, however, a mask layer 15 is formed between the first contact layer 14A and the second contact layer 14B.

The mask layer 15 changes a growing state of the second contact layer 14B. The mask layer 15 may be formed at a density less than 100% at the interface between the first contact layer 14A and the second contact layer 14B. For example, as illustrated in FIG. 5, the mask layer 15 is formed in an island shape on the first contact layer 14A. A constituent material of the mask layer 15 is an insulating material or an electrically conductive material. Examples of the insulating material include SiO₂ and silicon nitride (Si₃N₄).

In a case where the mask layer 15 is formed between the first contact layer 14A and the second contact layer 14B, the second contact layer 14B may be epitaxially grown in, for example, an island shape on the first contact layer 14A exposed from the mask layer 15. This increases the concentration of a dopant (e.g., Si) to be doped into the second contact layer 14B. Further, a surface roughness of the second contact layer 14B becomes larger, which increases a contact area between the source electrode S and the drain electrode D that are formed on the second contact layer 14B, and further decreases the contact resistance between the second contact layer 14B and the source electrode S and the contact resistance between the second contact layer 14B and the drain electrode D.

In the semiconductor device 1B according to the present modification example, the mask layer 15 is formed between the first contact layer 14A and the second contact layer 14B. This allows the second contact layer 14B to be formed in an island shape. This increases the carrier concentration of the second contact layer 14B and decreases the contact resistance between the second contact layer 14B and the source electrode S and the contact resistance between the second contact layer 14B and the drain electrode D, as compared with the above-described embodiment. It is therefore possible to provide a semiconductor device with higher output performance and higher efficiency.

### 2-3. Modification Example 3

FIG. 6 schematically illustrates an exemplary cross-sectional configuration of a semiconductor device (semiconductor device 1C) according to Modification Example 3 of the present disclosure.

In the example described in the foregoing embodiment, the contact layer 14 has the multilayer structure in which the first contact layer 14A and the second contact layer 14B having different carrier concentrations from each other are stacked. In the semiconductor device 1C of the present modification example, however, the carrier concentration increases continuously or gradually from the channel layer 12 toward the source electrode S and the drain electrode D within the contact layer 14.

Also in this configuration, effects similar to those of the above-described embodiment are obtainable.

### 2-4. Modification Example 4

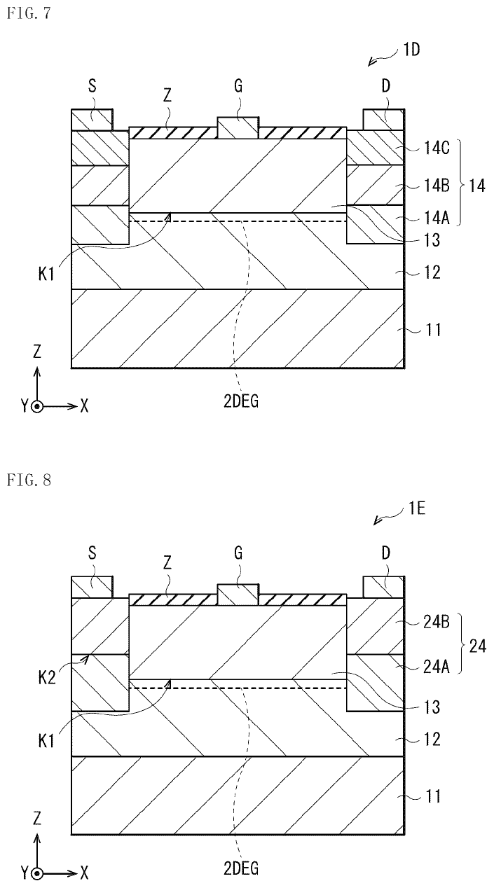

FIG. 7 schematically illustrates an exemplary cross-sectional configuration of a semiconductor device (semiconductor device 1D) according to Modification Example 4 of the present disclosure.

In the example described in the foregoing embodiment, the contact layer 14 has the two-layer structure in which the first contact layer 14A and the second contact layer 14B having different carrier concentrations from each other are stacked. The semiconductor device 1D of the present modification example, however, has a three-layer structure in which the first contact layer 14A, the second contact layer 14B, and a third contact layer 14C are stacked.

The third contact layer 14C includes GaN similarly to the first contact layer 14A and the second contact layer 14B. The third contact layer 14C includes a nitride semiconductor having a higher carrier concentration than the second contact layer 14B. For example, the third contact layer 14C has a carrier concentration within a range greater than or equal to 10¹⁸ cm⁻³ and less than or equal to 10²¹cm⁻³.

The contact layer 14 is not limited to the two-layer structure described above, and may have a multilayer structure including three or more layers. Also in this configuration, effects similar to those of the above-described embodiment are obtainable.

### 2-5. Modification Example 5

FIG. 8 schematically illustrates an exemplary cross-sectional configuration of a semiconductor device (semiconductor device 1E) according to Modification Example 5 of the present disclosure.

In the example described in the foregoing embodiment, the dopant included in the contact layer 14 is Si. In the semiconductor device 1E according to the present modification example, however, the contact layer 24 includes germanium (Ge) or oxygen (O) as a dopant. The first contact layer 24A and the second contact layer 24B each have a dopant concentration (carrier concentration) within a range greater than or equal to 10¹⁸ cm⁻³ and less than or equal to 10²¹ cm⁻³, similarly to the above-described embodiment.

Also in this configuration, effects similar to those of the above-described embodiment are obtainable.

### 2-6. Modification Example 6

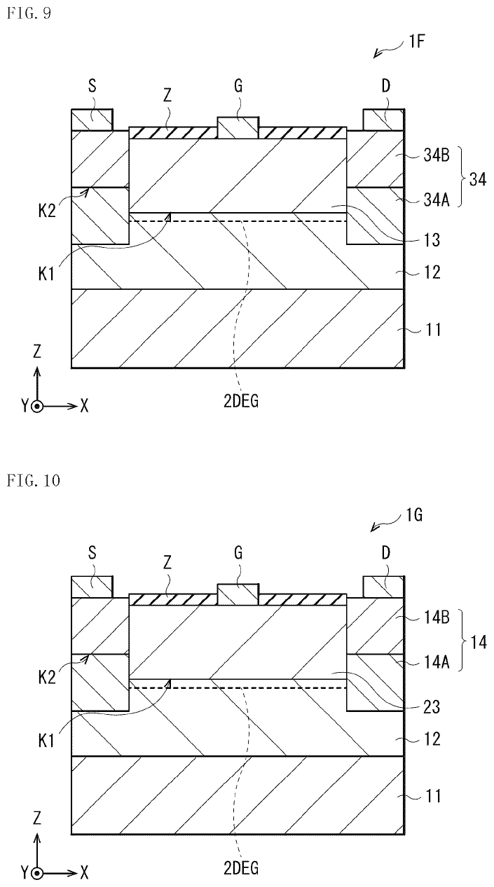

FIG. 9 schematically illustrates an exemplary cross-sectional configuration of a semiconductor device (semiconductor device 1F) according to Modification Example 6 of the present disclosure.

In the example described in the foregoing embodiment, the contact layer 14 includes gallium nitride (GaN). In the semiconductor device 1F according to the present modification example, the contact layer 34 includes Alₓ₁In_{y1}Ga_{(1-x1-y1)}N (0≤x1≤1, 0≤y1≤1, 0≤x1+y1≤1) that is a nitride semiconductor.

Also in this configuration, effects similar to those of the above-described embodiment are obtainable.

### 2-7. Modification Example 7

FIG. 10 schematically illustrates an exemplary cross-sectional configuration of a semiconductor device (semiconductor device 1G) according to Modification Example 7 of the present disclosure.

In the example described in the foregoing embodiment, the barrier layer 13 includes AlInN. In the semiconductor device 1G according to the present modification example, however, the barrier layer 23 includes, for example, indium gallium nitride (InGaN), indium nitride (InN), aluminum gallium nitride (AlGaN), or aluminum indium gallium nitride (AlInGaN) represented by Alₓ₂In_{y2}Ga_{(1-x2-y2)}N (0≤x2≤1, 0≤y2≤1).

Also in this configuration, effects similar to those of the above-described embodiment are obtainable.

### 2-8. Modification Example 8

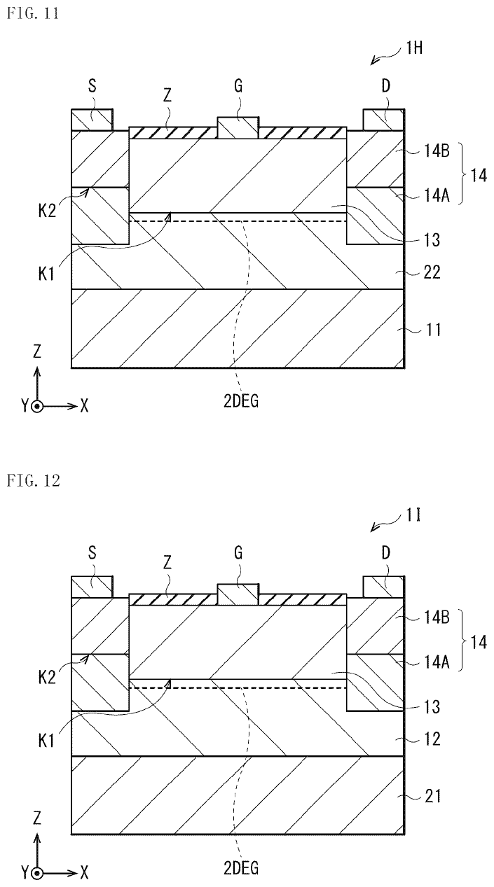

FIG. 11 schematically illustrates an exemplary cross-sectional configuration of a semiconductor device (semiconductor device 1H) according to Modification Example 8 of the present disclosure.

In the example described in the foregoing embodiment, the channel layer 12 includes GaN. In the semiconductor device 1H according to the present modification example, however, the channel layer 22 includes Alₓ₃In_{y3}Ga_{(1-x3-y3)}N (0≤x3≤1, 0≤y3≤1, 0≤x3+y3≤1).

For example, the channel layer 22 may include one or more of indium gallium nitride (InGaN), indium nitride (InN), aluminum gallium nitride (AlGaN), and aluminum indium gallium nitride (AlInGaN). Further, the channel layer 22 may have a stacked structure including multiple layers having different compositions. In these cases, the channel layer 22 makes it possible to suppress scattering of impurity of the carrier. It is therefore possible to improve the mobility of carrier of the channel layer 22.

Also in this configuration, effects similar to those of the above-described embodiment are obtainable.

### 2-9. Modification Example 9

FIG. 12 schematically illustrates an exemplary cross-sectional configuration of a semiconductor device (semiconductor device 1I) according to Modification Example 9 of the present disclosure.

In the example described in the foregoing embodiment, the substrate 11 is a Si substrate. In the semiconductor device 1I according to the present modification example, however, a sapphire substrate, a SiC substrate, a GaN substrate, an AIN substrate, a GaAs substrate, a ZnO substrate, a ScAlMgO substrate, or the like is used as the substrate 21.

It is to be noted that a semiconductor device 1 that includes a substrate including SiC or GaN superior in mono-crystallizability to Si (111) and lower in threading dislocation density than Si (111) is expected to reduce off-leak currents and withstand higher voltage. Accordingly, the substrate 21 may include a preferred material selected in accordance with the intended use, for example.

Also in this configuration, effects similar to those of the above-described embodiment are obtainable.

### 3. Application Examples

### 3-1. Semiconductor Module

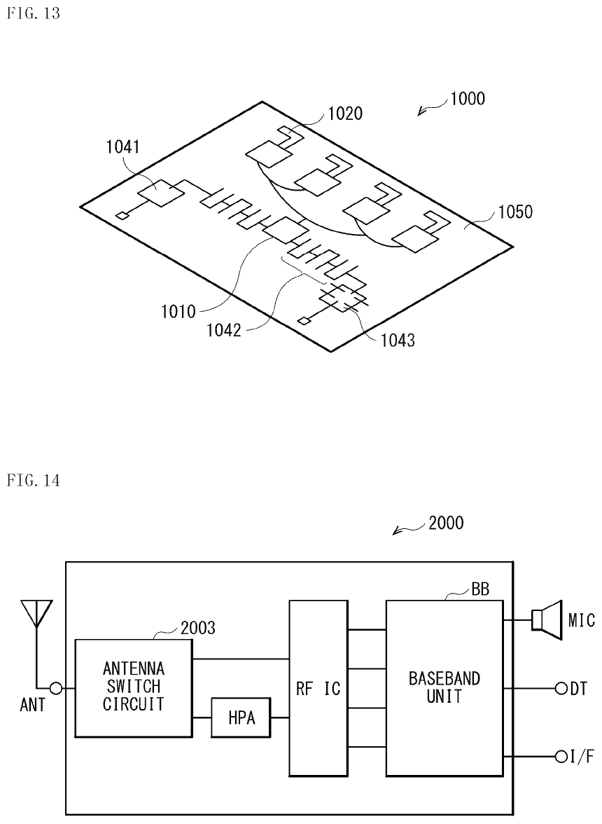

Next, a description is given of a semiconductor module that is a first application example of the technology according to the present disclosure, with reference to FIG. 13. FIG. 13 is a schematic perspective diagram of a configuration of a semiconductor module 1000.

As illustrated in FIG. 13, the semiconductor module 1000 is an antenna integrated module that includes, for example, an edge antenna 1020 and a plurality of front-end components mounted as modules on a single chip 1050. For example, a plurality of the edge antennas 1020 are formed in arrays on the chip 1050. The front-end components are, for example, a switch 1010, a low-noise amplifier 1041, a bandpass filter 1042, and a power amplifier 1043. The semiconductor module 1000 may be used a transceiver for wireless communication, for example.

The semiconductor module 1000 includes, for example, the semiconductor device according to the embodiment or the like described above (e.g., the semiconductor device 1), as a transistor including the switch 1010, the low-noise amplifier 1041 or the power amplifier 1043, and the like. For example, in a fifth generation (5G) mobile communication using electric waves in a further higher frequency band, a propagation loss of the electric waves increases. The semiconductor module 1000 for the 5G is thus desired to transmit electric waves with further higher electric power. The semiconductor module 1000 including the semiconductor device 1 makes it possible to improve device characteristics, and thus achieves high-output, low-power, high-reliability wireless communication. That is, it is possible to use the semiconductor module 1000 further preferably with respect to the 5G mobile communication.

### 3-2. Wireless Communication Apparatus

Next, a description is given of a wireless communication apparatus that is a second application example according to the present disclosure, with reference to FIG. 14. FIG. 14 is a block diagram illustrating a configuration of the wireless communication apparatus 2000.

As illustrated in FIG. 14, the wireless communication apparatus 2000 includes, for example, an antenna ANT, an antenna switch circuit 2003, a high-power amplifier HPA, a radio frequency integrated circuit (RFIC), a baseband unit BB, a sound output unit MIC, a data output unit DT, and an interface unit (I/F) (e.g., wireless local area network: W-LAN) or a Bluetooth. The wireless communication apparatus 2000 is a multifunctional mobile phone system that enables sound outputting, data communication, and LAN connection.

Upon transmission, the wireless communication apparatus 2000 causes the baseband unit BB to output a sending signal to the antenna ANT via the radio frequency integrated circuit RFIC, the high-power amplifier HPA, and an antenna switch circuit 203. Further, upon reception, the wireless communication apparatus 2000 causes the baseband unit BB to receive a receiving signal from the antenna ANT via the antenna switch circuit 2003 and the radio frequency integrated circuit RFIC. The signal processed at the baseband unit BB is outputted to outside the wireless communication apparatus 2000 from the sound output unit MIC, the data output unit DT, or the interface unit I/F, for example.

The wireless communication apparatus 2000 includes the semiconductor device (e.g., the semiconductor device 1) according to the above-described embodiment, as a transistor including the antenna switch circuit 2003, the high-power amplifier HPA, the radio frequency integrated circuit RFIC, the baseband unit BB, or the like. This makes it possible to further improve the device characteristics of the wireless communication apparatus 2000. It is therefore possible to perform low-power and high-reliability wireless communication.

The technology according to the present disclosure has been described with reference to the embodiment, Modification Examples 1 to 5, and the practical examples, and the application examples. However, the technology of the present disclosure is not limited to the embodiments and the like described above, and may be modified in a variety of ways.

Furthermore, not all of the configurations and operations described in the embodiments are essential as the configurations and operations of the present disclosure. For example, among the constituent elements in the embodiments, the constituent elements that are not described in the independent claim indicating the most significant concepts of the present disclosure should be understood as optional constituent elements.

The terms used in this specification and the appended claims should be interpreted as “non-limiting”. For example, the terms “comprising”, “including”, or “included” should be interpreted as “not limited to the manner described as being included.” The term “having” should be interpreted as “not limited to the manner described as having.”

The terminology used herein is for the convenience of description only and includes terminology that is not used to limit configuration and operation. For example, the terms “up,” “down,” and the like, merely indicate directions in the drawings with which they are referenced. The same applies to similar terms and terms having the same meaning.

It is to be noted that the effects described herein are mere examples and not limitative, and other effects may be provided.

It is to be noted that the present technology may have the following configurations. According to the configurations of the present technology, the contact resistance between the channel layer and the electrode provided on the second semiconductor layer is reduced. It is therefore possible to provide a high-output and high-efficiency semiconductor device.

(1) A semiconductor device including:
a substrate;
a channel layer including a first nitride semiconductor provided on one surface of the substrate;
a barrier layer including a second nitride semiconductor provided on a surface of the channel layer opposite to the substrate;
a first semiconductor layer partially buried in the surface of the channel layer opposite to the substrate and being in contact with the barrier layer at at least a part of a side surface; and
a second semiconductor layer provided on the first semiconductor layer and having a higher carrier concentration than the first semiconductor layer.

(2) The semiconductor device according to (1), including an interface between the first semiconductor layer and the second semiconductor layer located above the channel layer.

(3) The semiconductor device according to (1) or (2), in which
the barrier layer has a first surface opposed to the channel layer, and a second surface opposite to the first surface, and
an interface between the first semiconductor layer and the second semiconductor layer is located between the first surface and the second surface.

(4) The semiconductor device according to any one of (1) to (3), in which
the barrier layer has a first surface opposed to the channel layer and a second surface opposite to the first surface, and
an interface between the first semiconductor layer and the second semiconductor layer is located above the second surface of the barrier layer.

(5) The semiconductor device according to any one of (1) to (4), in which the second semiconductor layer is formed in an island shape on the first semiconductor layer.

(6) The semiconductor device according to any one of (1) to (5), further including a mask layer between the first semiconductor layer and the second semiconductor layer.

(7) The semiconductor device according to (6), in which the mask layer is formed in an island shape between the first semiconductor layer and the second semiconductor layer.

(8) The semiconductor device according to (6) or (7), in which the mask layer includes an insulating material or an electrically conductive material.

(9) The semiconductor device according to any one of (1) to (8), in which, when the first semiconductor layer and the second semiconductor layer are regarded as one layer, a carrier concentration continuously or gradually changes to increase from a surface of the first semiconductor layer opposite to the interface with the second semiconductor layer toward a surface of the second semiconductor layer opposite to the interface with the first semiconductor layer.

(10) The semiconductor device according to any one of (1) to (9), further including a third semiconductor layer provided on the second semiconductor layer and having a higher carrier concentration than the second semiconductor layer.

(11) The semiconductor device according to any one of (1) to (10), in which the carrier concentrations of the first semiconductor layer and the second semiconductor layer are greater than or equal to 10¹⁸ cm⁻³ and less than or equal to 10²¹ cm⁻³.

(12) The semiconductor device according to any one of (1) to (11), in which the first semiconductor layer and the second semiconductor layer each include one or more of silicon (Si), germanium (Ge), and oxygen (O) as a dopant.

(13) The semiconductor device according to any one of (1) to (12), in which the first semiconductor layer and the second semiconductor layer each include Alx1Iny1Ga(1-x1-y1)N (0≤x1≤1, 0≤y1≤1).

(14) The semiconductor device according to any one of (1) to (13), in which the barrier layer includes Alx2Iny2Ga_{(1-x2-y2)}N (0≤x2≤1, 0≤y2≤1).

(15) The semiconductor layer according to any one of (1) to (14), in which the channel layer includes Alx3Iny3Ga(1-x3-y3)N (0≤x3≤1, 0≤y3≤1).

(16) The semiconductor device according to any one of (1) to (15), in which the substrate includes one or more of silicon (Si), sapphire, silicon carbide (SiC), gallium nitride (GaN), and aluminum nitride (AlN).

(17) The semiconductor device according to any one of (1) to (16), in which
the barrier layer has a first surface opposed to the channel layer, and a second surface opposite to the first surface, and
an insulating film, a gate electrode, a source electrode, and a drain electrode are further provided on the second surface.

(18) The semiconductor device according to (17), in which
paired stacked bodies each including the first semiconductor layer and the second semiconductor layer are disposed with the barrier layer interposed therebetween,
the gate electrode is provided on the barrier layer, and
the source electrode and the drain electrode are respectively provided on the paired stacked bodies with the gate electrode interposed therebetween.

(19) A semiconductor module including a semiconductor device, the semiconductor device including:
a substrate;
a channel layer including a first nitride semiconductor provided on one surface of the substrate;
a barrier layer including a second nitride semiconductor provided on a surface of the channel layer opposite to the substrate;
a first semiconductor layer partially buried in the surface of the channel layer opposite to the substrate and being in contact with the barrier layer at at least a part of a side surface; and
a second semiconductor layer provided on the first semiconductor layer and having a higher carrier concentration than the first semiconductor layer.

(20) A wireless communication apparatus including a semiconductor device, the semiconductor device including:
a substrate;
a channel layer including a first nitride semiconductor provided on one surface of the substrate;
a barrier layer including a second nitride semiconductor provided on a surface of the channel layer opposite to the substrate;
a first semiconductor layer partially buried in the surface of the channel layer opposite to the substrate and being in contact with the barrier layer at at least a part of a side surface; and
a second semiconductor layer provided on the first semiconductor layer and having a higher carrier concentration than the first semiconductor layer.

What is claimed is:

1. A semiconductor device, comprising:
a substrate;
a channel layer including a first nitride semiconductor provided on one surface of the substrate;
a barrier layer including a second nitride semiconductor provided on a surface of the channel layer opposite to the substrate;
a first semiconductor layer partially buried in the surface of the channel layer opposite to the substrate and being in contact with the barrier layer at at least a part of a side surface; and
a second semiconductor layer provided on the first semiconductor layer and having a higher carrier concentration than the first semiconductor layer.

2. The semiconductor device according to claim 1, including an interface between the first semiconductor layer and the second semiconductor layer located above the channel layer.

3. The semiconductor device according to claim 1, wherein
the barrier layer has a first surface opposed to the channel layer, and a second surface opposite to the first surface, and
an interface between the first semiconductor layer and the second semiconductor layer is located between the first surface and the second surface.

4. The semiconductor device according to claim 1, wherein
the barrier layer has a first surface opposed to the channel layer and a second surface opposite to the first surface, and
an interface between the first semiconductor layer and the second semiconductor layer is located above the second surface of the barrier layer.

5. The semiconductor device according to claim 1, wherein the second semiconductor layer is formed in an island shape on the first semiconductor layer.

6. The semiconductor device according to claim 1, further comprising a mask layer between the first semiconductor layer and the second semiconductor layer.

7. The semiconductor device according to claim 6, wherein the mask layer is formed in an island shape between the first semiconductor layer and the second semiconductor layer.

8. The semiconductor device according to claim 6, wherein the mask layer includes an insulating material or an electrically conductive material.

9. The semiconductor device according to claim 1, wherein, when the first semiconductor layer and the second semiconductor layer are regarded as one layer, a carrier concentration continuously or gradually changes to increase from a surface of the first semiconductor layer opposite to the interface with the second semiconductor layer toward a surface of the second semiconductor layer opposite to the interface with the first semiconductor layer.

10. The semiconductor device according to claim 1, further comprising a third semiconductor layer provided on the second semiconductor layer and having a higher carrier concentration than the second semiconductor layer.

11. The semiconductor device according to claim 1, wherein the carrier concentrations of the first semiconductor layer and the second semiconductor layer are greater than or equal to 10¹⁸ cm⁻³ and less than or equal to 10²¹ cm⁻³.

12. The semiconductor device according to claim 1, wherein the first semiconductor layer and the second semiconductor layer each include one or more of silicon (Si), germanium (Ge), and oxygen (O) as a dopant.

13. The semiconductor device according to claim 1, wherein the first semiconductor layer and the second semiconductor layer each include Alₓ₁In_{y1}Ga_{(1-x1-y1)}N (0≤x1≤1, 0≤y1≤1).

14. The semiconductor device according to claim 1, wherein the barrier layer includes Alₓ₂In_{y2}Ga_{(1-x2-y2)}N (0≤x2≤1, 0≤y2≤1).

15. The semiconductor layer according to claim 1, wherein the channel layer includes Alₓ₃In_{y3}Ga_{(1-x3-y3)}N (0≤x3≤1, 0≤y3≤1).

16. The semiconductor device according to claim 1, wherein the substrate includes one or more of silicon (Si), sapphire, silicon carbide (SiC), gallium nitride (GaN), and aluminum nitride (AlN).

17. The semiconductor device according to claim 1, wherein
the barrier layer has a first surface opposed to the channel layer, and a second surface opposite to the first surface, and
an insulating film, a gate electrode, a source electrode, and a drain electrode are further provided on the second surface.

18. The semiconductor device according to claim 17, wherein
paired stacked bodies each including the first semiconductor layer and the second semiconductor layer are disposed with the barrier layer interposed therebetween,
the gate electrode is provided on the barrier layer, and
the source electrode and the drain electrode are respectively provided on the paired stacked bodies with the gate electrode interposed therebetween.

19. A semiconductor module comprising a semiconductor device, the semiconductor device including:
a substrate;
a channel layer including a first nitride semiconductor provided on one surface of the substrate;
a barrier layer including a second nitride semiconductor provided on a surface of the channel layer opposite to the substrate;
a first semiconductor layer partially buried in the surface of the channel layer opposite to the substrate and being in contact with the barrier layer at at least a part of a side surface; and
a second semiconductor layer provided on the first semiconductor layer and having a higher carrier concentration than the first semiconductor layer.

20. A wireless communication apparatus comprising a semiconductor device, the semiconductor device including:
a substrate;
a channel layer including a first nitride semiconductor provided on one surface of the substrate;
a barrier layer including a second nitride semiconductor provided on a surface of the channel layer opposite to the substrate;
a first semiconductor layer partially buried in the surface of the channel layer opposite to the substrate and being in contact with the barrier layer at at least a part of a side surface; and
a second semiconductor layer provided on the first semiconductor layer and having a higher carrier concentration than the first semiconductor layer.
